(19) United States
(12) Patent Application Publication
(10) Pub. No.: US 2023/0145114 A1
(43) Pub. Date: May 11, 2023

(54) MEMORY SYSTEM DIRECTED MEMORY ADDRESS MANAGEMENT TECHNIQUES

(71) Applicant: Micron Technology, Inc., Boise, ID (US)

(72) Inventor: David Y. Kao, Frisco, TX (US)

(21) Appl. No.: 17/522,633

(22) Filed: Nov. 9, 2021

(51) Int. Cl. G06F 12/10

(52) U.S. Cl. CPC G06F 12/10; G06F 2212/657

(57) ABSTRACT

Methods, systems, and devices for memory address management techniques are described. A host system may transmit a write command to store data at a memory system without transmitting an address, such as a logical address, to the memory system. In some examples, the memory system may generate a physical address for the data using one or more pointers indicating starting addresses of available locations of the memory system. The memory system may transmit an indication of the generated address, such as the physical address, a corresponding logical address, or an indication of a selected pointer. In some cases, generating the address and storing the data may at least partially overlap in time.

### FIELD OF TECHNOLOGY

The following relates generally to one or more systems for memory and more specifically to memory address management techniques.

### BACKGROUND

Memory devices are widely used to store information in various electronic devices such as computers, user devices, wireless communication devices, cameras, digital displays, and the like. Information is stored by programing memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read, or sense, the state of one or more memory cells within the memory device. To store information, a component may write, or program, one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be volatile or non-volatile. Volatile memory cells (e.g., DRAM cells) may lose their programmed states over time unless they are periodically refreshed by an external power source. Non-volatile memory cells (e.g., NAND memory cells) may maintain their programmed states for extended periods of time even in the absence of an external power source.

### BRIEF DESCRIPTION OF THE DRAWINGS

FIG. 1 illustrates an example of a system that supports memory address management techniques in accordance with examples as disclosed herein.

FIG. 2 illustrates an example of a block diagram that supports memory address management techniques in accordance with examples as disclosed herein.

FIG. 3 illustrates an example of a process flow that supports memory address management techniques in accordance with examples as disclosed herein.

FIG. 4 shows a block diagram of a memory system that supports memory address management techniques in accordance with examples as disclosed herein.

FIG. 5 shows a block diagram of a host system that supports memory address management techniques in accordance with examples as disclosed herein.

FIGS. 6 through 8 show flowcharts illustrating a method or methods that support memory address management techniques in accordance with examples as disclosed herein.

### DETAILED DESCRIPTION

In some memory systems, a host system may transmit access commands, such as a write command to store data, to a memory system. The write command may include an indication of a location to store the data at the memory system, such as a logical address. After the memory system has received the write command, the logical address, and the data, the memory system translate the logical address to a physical address and store the data at the physical address. The host system may associate data to be written with a logical address, so that the host system may issue a second access command, such as a read command, which includes the logical address to the memory system to retrieve the data. However, the host system and memory system may use a large amount of system resources to manage and translate between logical addresses and physical addresses. For example, the memory system may delay storing until the logical address has been received and translated to a physical address. Techniques to improve efficiency of managing memory addresses are desired.

As described herein, the host system may not generate an address as part of issuing a write command the memory system. Instead, the host system may transmit the write command and the associated data to the memory system. The memory system may generate an address, such as a logical address or a physical address, corresponding to a location of store the data. For example, the memory system may select a location to store the data using a pointer. In some cases, the pointer may indicate a starting address or location of available memory cells. The memory system may transmit the address to the host system, and the host system may associate the data with the address. In some examples, the memory system may generate the address while performing the write command (e.g., the data may be stored in parallel with generating the address), which may more efficiently utilize system resources. Accordingly, the host system may complete the write operation corresponding to the write command in fewer operations (e.g., compared to a method in which the host system generates a logical address for a write command) and thus reduce system latency.

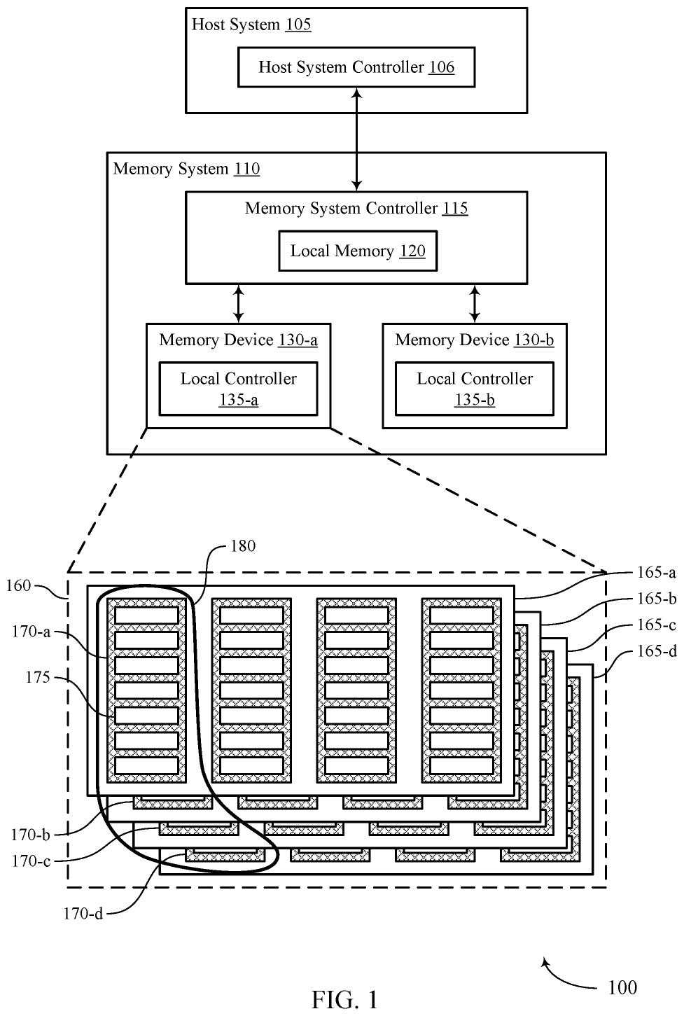

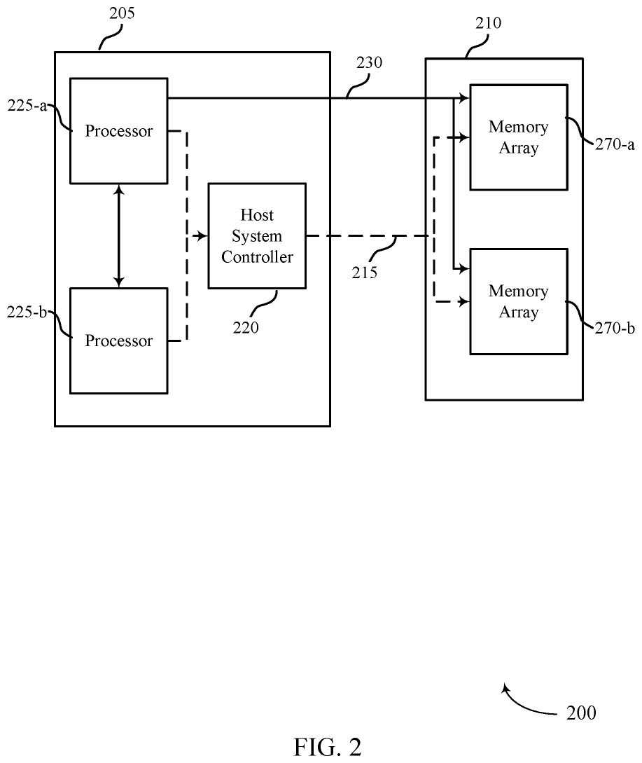

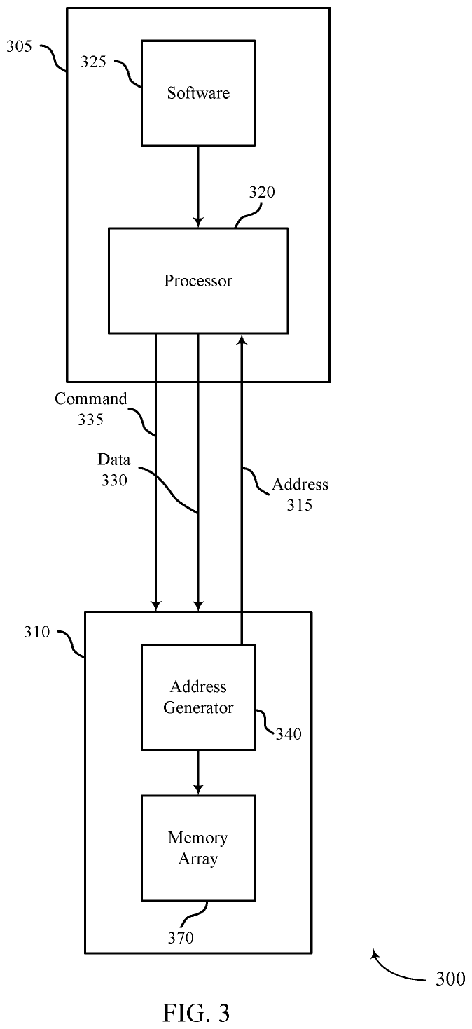

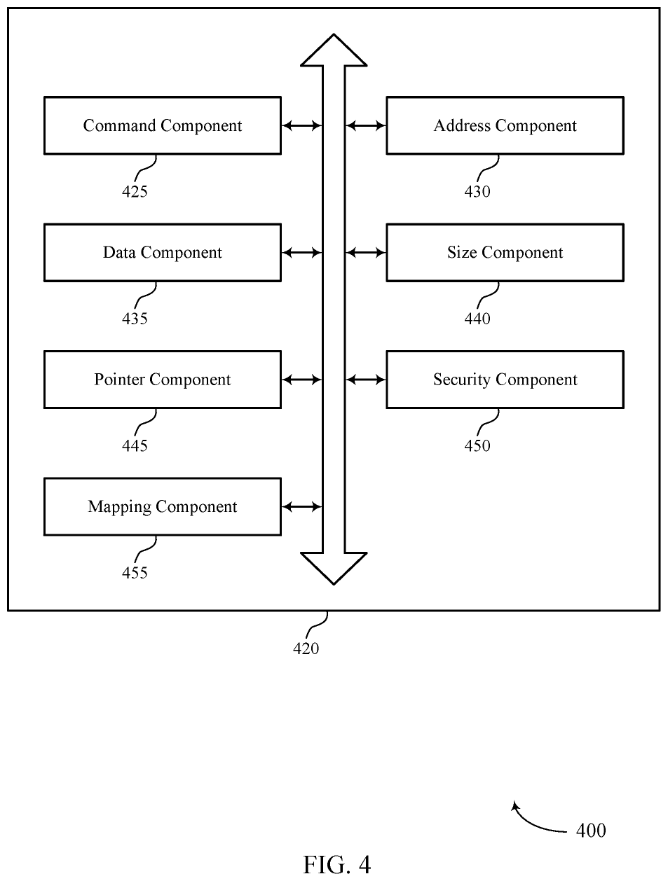

Features of the disclosure are initially described in the context of systems, devices, and circuits with reference to FIG. 1. Features of the disclosure are described in the context of a block diagram and process flow with reference to FIGS. 2-3. These and other features of the disclosure are further illustrated by and described in the context of an apparatus diagram and flowchart that relate to memory address management techniques with reference to FIGS. 4-8.

FIG. 1 illustrates an example of a system 100 that supports memory address management techniques in accordance with examples as disclosed herein. The system 100 includes a host system 105 coupled with a memory system 110. In some examples, the host system 105 may be referred to as a host device and a memory system 110 may be referred to as a memory device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), a non-volatile DIMM (NVDIMM), a NAND device, a DRAM device, an FeRAM device, or a 3D cross point device, among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices, and in some cases may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may in some cases be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), a Low Power Double Data Rate (LPDDR) interface, a NAND interface, a DRAM interface, an FeRAM interface, and a 3D cross point interface,. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally or alternatively include static random access memory (SRAM) or other memory that may be used by the memory system controller 115 for internal storage or calculations, for example, related to the functions ascribed herein to the memory system controller 115. Additionally or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally or alternatively rely upon an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may in some cases instead be performed by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories including 3D cross point memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device), a DRAM device, an FeRAM device, a 3D cross point device, or any combination thereof. A memory device 130 may be or include a memory die 160. For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may take place within different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some memory architectures, such as NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may in some cases not be updated until the entire block 170 that includes the page 175 has been erased.

The system 100 may include any quantity of non-transitory computer readable media that support memory address management techniques. For example, the host system 105, the memory system controller 115, or a memory device 130 (e.g., a local controller 135) may include or otherwise may access one or more non-transitory computer readable media storing instructions (e.g., firmware) for performing the functions ascribed herein to the host system 105, memory system controller 115, or memory device 130. For example, such instructions, if executed by the host system 105 (e.g., by the host system controller 106), by the memory system controller 115, or by a memory device 130 (e.g., by a local controller 135), may cause the host system 105, memory system controller 115, or memory device 130 to perform one or more associated functions as described herein.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some cases, the host system 105 may not generate an address as part of issuing a write command the memory system 110. Instead, the host system 105 may transmit the write command and the associated data to the memory system 110. The memory system 110 may generate an address, such as a physical address, corresponding to a location to store the data. For example, the memory system 110 may select a location to store the data using a pointer. In some cases, the pointer may indicate a starting address or location of available memory cells. The memory system 110 may transmit the address to the host system 105, and the host system 105 may associate the data with the address. In some examples, the memory system 110 may generate the address while performing the write command (e.g., the data may be stored in parallel with generating the address), which may more efficiently utilize system resources. Accordingly, the host system 105 and memory system 110 may complete the write operation corresponding to the write command in fewer operations (e.g., compared to a method in which the host system 105 generates a logical address for a write command) and thus reduce system latency.

FIG. 2 illustrates an example of a block diagram 200 that supports memory address management techniques in accordance with examples as disclosed herein. The block diagram 200 may include a host system 205 and a memory system 210, which may be examples of a host system 105 and a memory system 110 as described with reference to FIG. 1. For example, the memory system 210 may be an example of a volatile memory device, such as a DRAM device or an FeRAM device, or the memory system 210 may be an example of a non-volatile memory device, such as a NAND device, a NOR device, an SSD disk, or a jump drive, among other examples.

The host system 205 may include a quantity of processors 225, such as a first processor 225-a and a second processor 225-b. For example, the host system may include a multi-core processor. The host system 205 may issue commands for performing access operations to the memory system 210, such as write commands for storing data at the memory system 210 or read commands for accessing data stored at the memory system 210. In some cases, the data stored at the memory system 210 may be stored in one or more memory arrays 270, such as the memory array 270-a or the memory array 270-b. In some examples, the memory arrays 270 may include non-volatile memory cells (e.g., the memory system 210 may be a non-volatile memory system). In other examples, the memory arrays 270 may include volatile memory cells (e.g., the memory system 210 may be a volatile memory system). The memory arrays 270 may be an example of a memory array 170 as described with reference to FIG. 1.

In some examples, as part of issuing access commands to the memory system 210, the host system 205 may transmit an address 215 for data 230 associated with the access command. For example, the host system 205 may issue a write command to store data at the memory system 210. As part of issuing the write command, the host system 205 may generate the address 215 using a host system controller 220, which may be an example of the external memory controller 120 as described with reference to FIG. 1. The host system 205 may associate the address 215 with the data 230, so that if the host system 205 issues a subsequent command to access the data 230 (e.g., a read command), the host system 205 may issue the address 215 associated with the data 230 to the memory system 210 to retrieve the data 230. In some cases, the host system controller 220 may manage addresses associated with data. In some cases, the addresses managed by the host system controller 220 may be referred to as logical addresses. In some cases, in response to receiving the address 215 (e.g., a logical address), the memory system 210 may generate a physical address corresponding to a location of the memory arrays 270 to store the data 230. In such cases, the memory system 210 may manage a mapping between logical addresses and physical addresses. In some cases, the host system 205 may delay transmitting the data 230 to the memory system 210 until the address 215 has been transmitted, which may increase system latency.

In other examples, the host system controller 220 may not generate an address as part of issuing a write command from the host system 205 to the memory system 210. Instead, the host system 205 may transmit the write command and the associated data 230 to the memory system 210. The memory system 210 may generate an address, such as a physical address, corresponding to a location of the memory arrays 270 to store the data 230. For example, the memory system may select a location to store the data 230 using a pointer. In some cases, the pointer may indicate a starting address or location of available memory cells in one or more of the memory arrays 270. In some cases, the memory system 210 may transmit the address to the host system 205, and the host system 205 may associate the data with the address.

In some examples, the memory system 210 may generate the address while performing the write command (e.g., the data 230 may be stored in parallel with generating the address), which may more efficiently utilize system resources. Accordingly, the host system 205 may complete the write operation corresponding to the write command in fewer operations (e.g., compared to a method in which the host system 205 generates a logical address for a write command) and thus reduce system latency.

FIG. 3 illustrates an example of a process flow 300 that supports memory address management techniques in accordance with examples as disclosed herein. The process flow 300 may illustrate an example flow of a write operation issued by a host system 305 to store data 330 at a memory array 370 of a memory system 310. In the following description of process flow 300, the operations may be performed in a different order than the order shown. For example, specific operations may also be left out of process flow 300, or other operations may be added to process flow 300.

By way of example, the host system 305 may execute a program or software 325 using a processor 320. As part of executing the software 325, the host system 305 may store data, such as variables or other information used in the software 325, at the memory system 310. For example, the host system 305 may transmit a command 335, which may be an example of a write command, to the memory system 310. The command 335 may indicate to the memory system 310 that the host system 305 may transmit data 330 to the memory system 310 to be stored at a location of the memory array 370.

In some cases, the command 335 may include a size or length of the data 330. For example, the command 335 may include an indication of a quantity of bits of the data 330. Additionally or alternatively, the command 335 may indicate a duration of a burst mode or transmission mode used to transmit the data 330 from the host system 305 to the memory system, an indication of a quantity of channels used to transmit the data 330 from the host system 305 to the memory system, or both. In some cases, after transmitting the command 335, the host system 305 may transmit the data 330 to the memory system 310.

In some cases, the command 335 and the data 330 transmitted to the memory system 310 may not include an address, such as a logical address or physical address, for the data 330. Instead, the memory system 310 may determine an address for the data 330. For example, the memory system 310 may include an address generator 340, which may determine or identify one or more free or available locations (e.g., one or more memory cells available for storage) of the memory array 370. In some cases, the address generator 340 may include a size calculator or other logic to determine or identify the size of the data 330. In other cases, the host system 305 may transmit an indication of the size of the data 330 as part of the command 335.

After receiving the data 330, the memory system 310 may temporarily store the data 330 at a buffer, such as an input data buffer, while determining a location of the memory array 370 to store the data 330. In some cases, the address generator 340 may track or identify free or available locations by creating or selecting one or more internal pointers of the memory system 310. In some cases, a pointer may correspond to or be a starting address for a contiguous block or region of available memory cells of the memory array 370 (e.g., the pointer may be a free memory pointer (FMP) or an address pointer). In some cases, a pointer may include an indication of the size of available memory cells corresponding to the pointer.

The memory system 310 may include multiple pointers corresponding to different sizes or types of available memory cells. For example, if the memory system 310 is a NAND memory system, the memory system 310 may include a first pointer corresponding to one or more SLC blocks and a second pointer corresponding to one or more multiple level cell blocks, such as MLC blocks, TLC blocks, or QLC blocks. In some cases, the memory system 310 may include a pointer corresponding to a relatively small quantity of available blocks, for example a page of memory cells. Additionally or alternatively, the memory system 310 may include a pointer corresponding to a relatively large quantity of blocks, such as all or a substantial portion of a memory die.

The address generator 340 may determine to store the data 330 at the one or more available cells. For example, the address generator 340 may select a pointer with a size of available memory cells sufficiently large to store the data 330. Accordingly, the address generator 340 may determine to store the data 330 at the associated address of the pointer. Additionally or alternatively, the address generator 340 may determine to store the data across multiple regions of available memory cells (e.g., at locations associated with multiple pointers).

Using the selected one or more pointers, the address generator 340 may generate an indication of an address 315 of the data 330. For example, the address generator 340 may generate a starting physical address (e.g., corresponding to the selected pointer) and associated size of data stored at the starting physical address. In some cases, the address generator 340 may generate a starting physical address and an ending physical address (e.g., an address corresponding to the location of the last memory cell written to). In other cases, the address 315 may include an indication of the selected pointer or pointers. For example, the address 315 may include an indication of a name of the selected pointer, a value of the selected pointer, an address of the selected pointer, or any combination thereof.

In some cases, the address generator 340 may generate a logical address for the data 330. In such cases, the memory system may store or manage a mapping, such as a data table or lookup table, which relates the generated logical address with the physical address or physical addresses of the selected pointer or pointers. Additionally or alternatively, the mapping may relate the logical address directly with the selected pointer or pointers.

In some examples, the host system 305 may request an indication of the mapping from the memory system 310. For example, the host system 305 may transmit a command to retrieve the mapping to the memory system 310. In some cases, the host system 305 may additionally transmit a passcode or other security parameter along with the command to retrieve the mapping to the memory system 310. The memory system 310 may verify the passcode, for example by comparing the passcode to entries of a table of authorized users. In some cases, if the passcode appears in the table, the memory system 310 may transmit all or a portion of the mapping to the host system 305. Additionally or alternatively, if the passcode does not appear in the table, the memory system 310 may transmit an indication that the command to retrieve the mapping may not be authorized to the host system 305.

In some examples, the memory system 310 may allocate a quantity of memory cells (e.g., at the location corresponding to the generated address 315) for the data 330. In some cases, the size allocated for the data 330 may be larger than the data 330. For example, the command 335 may indicate that the data 330 may be dynamic (e.g., a dynamic array), which may be appended or added to in subsequent write commands. Accordingly, the size of the allocated memory cells may be adjusted (e.g., the memory system may allocate additionally memory cells) as the data 330 is adjusted according to the software 325.

The memory system 310 may transmit the indication of the address 315 (e.g., a physical address, a logical address, or an indication of the selected pointer) generated by the address generator 340 to the host system 305. In some cases, the memory system 310 may transmit the address 315 directly to the processor 320 of the host system 305 (e.g., the address 315 may not be routed or transferred through a controller of the host system 305). After receiving the address 315, the host system 305 may store the address 315. Additionally or alternatively, the host system 305 may associate the address with the data 330. For example, the host system 305 may include a mapping (e.g., as part of executing software 325) between data used by the software 325 and associated addresses received from the memory system 310. In some cases, the host system 305 may keep the write command “open” (e.g., store aspects or parameters of the write command in a buffer at the host system 305) after transmitting the command 335. In some cases, keeping the write command open may include storing the command 335 at the host system 305. After the host system 305 receives the address 315 for the data 330 from the memory system 310, the host system 305 may “close” the write command (e.g., clear the buffer, associate the data with the address, or both).

In some cases, after the address generator 340 has determined a location for the data 330, the memory system 310 may store the data at the determined location. For example, the memory system 310 may open an access path between the input data buffer and the determined location of the memory array 370. In some cases (e.g., if the address generator 340 determined to store the data 330 across multiple locations), the access path may include multiple channels or paths, corresponding to the determined locations. In some cases, the data 330 may be sequentially stored at the determined locations. For example, a first portion of the data 330 may be stored at the starting address, a second portion of the data 330 may be stored at an address consecutive with the starting address, and so on, until all portions of the data 330 have been stored. Because the address generator 340 may generate the address 315 prior to the memory system 310 storing the data 330, the memory system 310 may transmit the address 315 to the host system 305 and store the data 330 in parallel. For example, the operation to transmit the address 315 and the operation to store the data 330 may at least partially overlap in time, which may reduce system latency by improving the efficiency of resources sued by the host system 305 and memory system 310.

In some examples, after transferring the data from the input data buffer to the one or more determined locations, the selected one or more pointers may be updated. For example, the memory system 310 may adjust a value or address of the pointer to correspond to a next free location of the memory array 370. In some cases, the next free location of the memory array 370 may be at an address consecutive with the last address written as part of storing the data 330. Additionally or alternatively, the next free location of the memory array 370 may correspond to a region of memory cells with a threshold size or quantity of available memory cells.

In some examples, there may not be sufficient memory cells to store the data 330. Accordingly, the address generator 340 generate an address 315 indicating that the memory system 310 may be full or otherwise unable to store the data 330. For example, the address generator 340 may generate an address 315 corresponding to a last logical address (e.g., an address in which each bit included in the address is a logical “1”). If the host system 305 receives an address indicating that the memory system 310 may be unable to store the data 330, the host system 305 may an erase command or issue an indication to perform a data compression to the memory system 310 prior to re-issuing the command 335.

In some cases, after the host system 305 receives the address 315 and associates the address 315 with the data 330, the host system 305 may, as part of executing the software 325, transmit a read command for the data 330 to the memory system 310. In some cases, the read command may include the address 315 stored at the host system 305.

The memory system 310 may receive the read command and the address 315 from the host system 305. In some cases (e.g., if the address 315 includes a logical address or an indication of the selected pointer), the memory system 310 may, using the address generator 340, convert or translate the address 315 into a physical address. For example, the memory system 310 may generate a physical address using a logical address transmitted by the host system 305. The memory system 310 may retrieve the data 330 stored at the physical address and subsequently transmit the data 330 back to the host system 305.

In some cases, the memory array 370 may include volatile memory cells (e.g., the memory system 310 may be an example of a volatile memory system, such as a DRAM device). In such cases, the timing of the transmission of the command 335, the data 330, and the address 315 between the host system 305 and the memory system 310 may be adjusted in accordance with the memory system 310 generating the address 315. For example, the host system 305 may transmit the command 335 during a first set of clock cycles and may transmit the data during a second set of clock cycles. The memory system 310 may receive the command 335 during the first set of clock cycles and the data 330 during the second set of clock cycles. In some cases, the memory system 310 may generate the address 315 during the first set of clock cycles, the second set of clock cycles, or both. The memory system 310 may transmit the address 315 to the host system 305 during a third set of clock cycles. In some cases, the third set of clock cycles may at least partially overlap in time with the second set of clock cycles (e.g., the memory system 310 may transmit the address 315 at a same time that the host system 305 transmits the data 330). In some examples, the memory system 310 may buffer the data 330 (e.g., in an input data buffer) after receiving the data 330 and before transmitting the address 315.

In some cases, the memory array 370 may include non-volatile memory cells (e.g., the memory system 310 may be an example of a non-volatile memory system, such as a NAND device). In such cases, the timing of the transmission of the command 335, the data 330, and the address 315 between the host system 305 and the memory system 310 may be adjusted in accordance with the memory system 310 generating the address 315. For example, the host system 305 may transmit a prefix for the command 335 and the command 335 during a first set of transmission cycles and may transmit the data during a second set of transmission cycles. The memory system 310 may receive the command 335 during the first set of transmission cycles and the data 330 during the second set of transmission cycles. In some cases, the memory system 310 may generate the address 315 during the first set of transmission cycles, the second set of transmission cycles, or both. The memory system 310 may transmit the address 315 to the host system 305 during a third set of transmission cycles. In some cases, the third set of transmission cycles may at least partially overlap in time with the second set of transmission cycles (e.g., the memory system 310 may transmit the address 315 at a same time that the host system 305 transmits the data 330).

FIG. 4 shows a block diagram 400 of a memory system 420 that supports memory address management techniques in accordance with examples as disclosed herein. The memory system 420 may be an example of aspects of a memory system as described with reference to FIGS. 1 through 3. The memory system 420, or various components thereof, may be an example of means for performing various aspects of memory address management techniques as described herein. For example, the memory system 420 may include a command component 425, an address component 430, a data component 435, a size component 440, a pointer component 445, a security component 450, a mapping component 455, or any combination thereof. Each of these components may communicate, directly or indirectly, with one another (e.g., via one or more buses).

The command component 425 may be configured as or otherwise support a means for receiving, from a host system, a command to store data in a memory system and the data associated with the command. The address component 430 may be configured as or otherwise support a means for generating, at the memory system, an address to store the data based at least in part on receiving the command and the data, the address based at least in part on a size of the data. In some examples, the address component 430 may be configured as or otherwise support a means for transmitting the address to the host system based at least in part on generating the address. The data component 435 may be configured as or otherwise support a means for storing the data at a location indicated by the address based at least in part on generating the address.

In some examples, the command does not include an indication of a logical address associated with the data.

In some examples, the size component 440 may be configured as or otherwise support a means for identifying the size of the data based at least in part on receiving the command and the data, where generating the address is based at least in part on identifying the size of the data.

In some examples, the command includes an indication of the size of the data and identifying the size of the data is based at least in part on the indication included in the command.

In some examples, the pointer component 445 may be configured as or otherwise support a means for using a pointer of the memory system that indicates one or more memory cells available to store the data based at least in part on the size of the data, where generating the address is based at least in part on using the pointer.

In some examples, the address component 430 may be configured as or otherwise support a means for identifying a starting physical address of the memory system for the data based at least in part on the pointer, where generating the address is based at least in part on identifying the starting physical address.

In some examples, the pointer component 445 may be configured as or otherwise support a means for updating the pointer based at least in part on storing the data and the size of the data, where the address includes a value of the pointer, a name of the pointer, an address of the pointer, or a combination thereof.

In some examples, to support generating the address, the address component 430 may be configured as or otherwise support a means for identifying a physical address to store the data based at least in part on a pointer of the memory system and the size of the data. In some examples, to support generating the address, the address component 430 may be configured as or otherwise support a means for generating a logical address based at least in part on the physical address, where the address that is transmitted to the host system includes the logical address.

In some examples, the command component 425 may be configured as or otherwise support a means for receiving, from the host system, a command to retrieve a mapping between the physical address and the logical address (e.g., a second command). In some examples, the security component 450 may be configured as or otherwise support a means for receiving, from the host system, a security parameter associated with the command to retrieve the mapping. In some examples, the mapping component 455 may be configured as or otherwise support a means for transmitting at least a portion of the mapping to the host system based at least in part on receiving the command to retrieve the mapping and the security parameter.

In some examples, to support storing the data, the data component 435 may be configured as or otherwise support a means for storing the data at the location indicated by the pointer of the memory system, where identifying the physical address is based at least in part on the pointer, and where storing the data at least partially overlaps in time with generating the address.

In some examples, to support generating the address, the address component 430 may be configured as or otherwise support a means for identifying a physical address to store the data based at least in part on a pointer of the memory system and the size of the data, where the address that is transmitted to the host system includes the physical address.

In some examples, the data component 435 may be configured as or otherwise support a means for allocating a quantity of memory cells for the data associated with the command based at least in part on the size of the data, where storing the data is based at least in part on the address and allocating the quantity of memory cells.

In some examples, the quantity of memory cells includes volatile memory cells. In some examples, the quantity of memory cells includes non-volatile memory cells.

In some examples, the command component 425 may be configured as or otherwise support a means for receiving, from a host system, a command to retrieve data stored in a memory system. In some examples, the address component 430 may be configured as or otherwise support a means for receiving an address for the data, the address generated at the memory system and based at least in part on a size of the data. In some examples, the data component 435 may be configured as or otherwise support a means for transmitting the data to the host system based at least in part on receiving the command.

In some examples, the data component 435 may be configured as or otherwise support a means for retrieving, based at least in part on receiving the command and the address, the data from the memory system using the address generated at the memory system, where transmitting the data is based at least in part on retrieving the data.

In some examples, the address component 430 may be configured as or otherwise support a means for generating, based at least in part on receiving the command and the address generated at the memory system, a physical address associated with the data, where transmitting the data is based at least in part on generating the physical address.

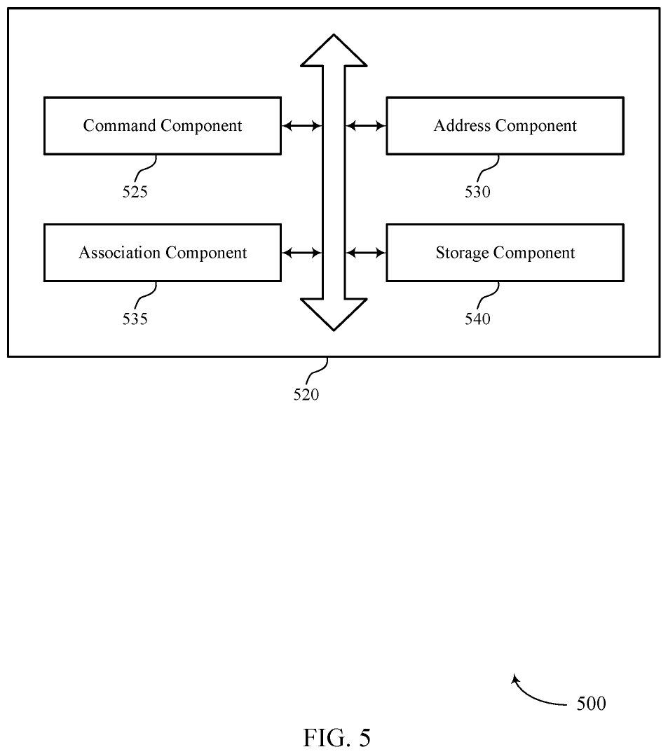

FIG. 5 shows a block diagram 500 of a host system 520 that supports memory address management techniques in accordance with examples as disclosed herein. The host system 520 may be an example of aspects of a host system as described with reference to FIGS. 1 through 3. The host system 520, or various components thereof, may be an example of means for performing various aspects of memory address management techniques as described herein. For example, the host system 520 may include a command component 525, an address component 530, an association component 535, a storage component 540, or any combination thereof. Each of these components may communicate, directly or indirectly, with one another (e.g., via one or more buses).

The command component 525 may be configured as or otherwise support a means for transmitting, to a memory system, a command to store data in the memory system and the data associated with the command. The address component 530 may be configured as or otherwise support a means for receiving, at a host system, an address for the data based at least in part on transmitting the command and the data, the address generated at the memory system and based at least in part on a size of data. The association component 535 may be configured as or otherwise support a means for associating the address with the data based at least in part on receiving the address.

In some examples, the storage component 540 may be configured as or otherwise support a means for storing the address at the host system based at least in part on associating the address with the data.

In some examples, the storage component 540 may be configured as or otherwise support a means for storing the command at the host system based at least in part on transmitting the command, where receiving the address is based at least part on storing the command.

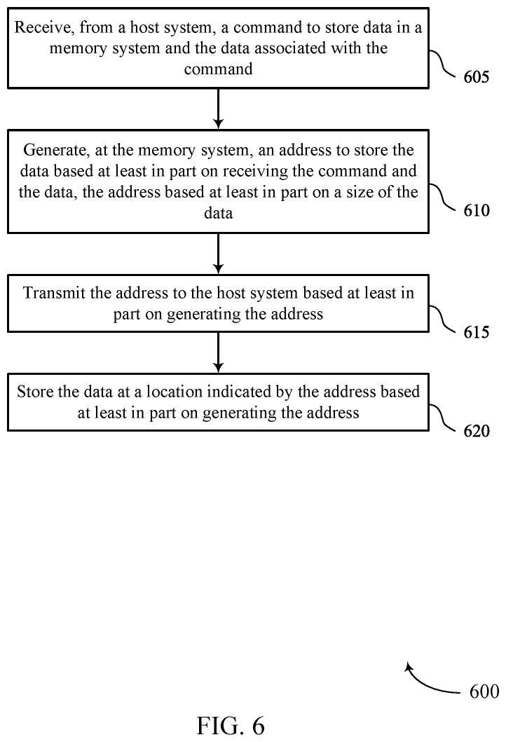

FIG. 6 shows a flowchart illustrating a method 600 that supports memory address management techniques in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally or alternatively, the memory system may perform aspects of the described functions using special-purpose hardware.

At 605, the method may include receiving, from a host system, a command to store data in a memory system and the data associated with the command. The operations of 605 may be performed in accordance with examples as disclosed herein. In some examples, aspects of the operations of 605 may be performed by a command component 425 as described with reference to FIG. 4.

At 610, the method may include generating, at the memory system, an address to store the data based at least in part on receiving the command and the data, the address based at least in part on a size of the data. The operations of 610 may be performed in accordance with examples as disclosed herein. In some examples, aspects of the operations of 610 may be performed by an address component 430 as described with reference to FIG. 4.

At 615, the method may include transmitting the address to the host system based at least in part on generating the address. The operations of 615 may be performed in accordance with examples as disclosed herein. In some examples, aspects of the operations of 615 may be performed by an address component 430 as described with reference to FIG. 4.

At 620, the method may include storing the data at a location indicated by the address based at least in part on generating the address. The operations of 620 may be performed in accordance with examples as disclosed herein. In some examples, aspects of the operations of 620 may be performed by a data component 435 as described with reference to FIG. 4.

In some examples, an apparatus as described herein may perform a method or methods, such as the method 600. The apparatus may include, features, circuitry, logic, means, or instructions (e.g., a non-transitory computer-readable medium storing instructions executable by a processor), or any combination thereof for performing the following aspects of the present disclosure:

Aspect 1: The method or apparatus, including operations, features, circuitry, logic, means, or instructions, or any combination thereof for receiving, from a host system, a command to store data in a memory system and the data associated with the command; generating, at the memory system, an address to store the data based at least in part on receiving the command and the data, the address based at least in part on a size of the data; transmitting the address to the host system based at least in part on generating the address; and storing the data at a location indicated by the address based at least in part on generating the address.

Aspect 2: The method or apparatus of aspect 1, further including operations, features, circuitry, logic, means, or instructions, or any combination thereof for the command does not include an indication of a logical address associated with the data.

Aspect 3: The method or apparatus of any of aspects 1 through 2, further including operations, features, circuitry, logic, means, or instructions, or any combination thereof for identifying the size of the data based at least in part on receiving the command and the data, where generating the address is based at least in part on identifying the size of the data.

Aspect 4: The method or apparatus of aspect 3, further including operations, features, circuitry, logic, means, or instructions, or any combination thereof for the command includes an indication of the size of the data and identifying the size of the data is based at least in part on the indication included in the command.

Aspect 5: The method or apparatus of any of aspects 1 through 4, further including operations, features, circuitry, logic, means, or instructions, or any combination thereof for using a pointer of the memory system that indicates one or more memory cells available to store the data based at least in part on the size of the data, where generating the address is based at least in part on using the pointer.

Aspect 6: The method or apparatus of aspect 5, further including operations, features, circuitry, logic, means, or instructions, or any combination thereof for identifying a starting physical address of the memory system for the data based at least in part on the pointer, where generating the address is based at least in part on identifying the starting physical address.

Aspect 7: The method or apparatus of any of aspects 5 through 6, further including operations, features, circuitry, logic, means, or instructions, or any combination thereof for updating the pointer based at least in part on storing the data and the size of the data, where the address includes a value of the pointer, a name of the pointer, an address of the pointer, or a combination thereof.

Aspect 8: The method or apparatus of any of aspects 1 through 7 where generating the address, further includes operations, features, circuitry, logic, means, or instructions, or any combination thereof for identifying a physical address to store the data based at least in part on a pointer of the memory system and the size of the data and generating a logical address based at least in part on the physical address, where the address that is transmitted to the host system includes the logical address.

Aspect 9: The method or apparatus of aspect 8, further including operations, features, circuitry, logic, means, or instructions, or any combination thereof for receiving, from the host system, a second command to retrieve a mapping between the physical address and the logical address; receiving, from the host system, a security parameter associated with the second command to retrieve the mapping; and transmitting at least a portion of the mapping to the host system based at least in part on receiving the second command to retrieve the mapping and the security parameter.

Aspect 10: The method or apparatus of any of aspects 8 through 9 where storing the data, further includes operations, features, circuitry, logic, means, or instructions, or any combination thereof for storing the data at the location indicated by the pointer of the memory system, where identifying the physical address is based at least in part on the pointer, and where storing the data at least partially overlaps in time with generating the address.

Aspect 11: The method or apparatus of any of aspects 1 through 10 where generating the address, further includes operations, features, circuitry, logic, means, or instructions, or any combination thereof for identifying a physical address to store the data based at least in part on a pointer of the memory system and the size of the data, where the address that is transmitted to the host system includes the physical address.

Aspect 12: The method or apparatus of any of aspects 1 through 11, further including operations, features, circuitry, logic, means, or instructions, or any combination thereof for allocating a quantity of memory cells for the data associated with the command based at least in part on the size of the data, where storing the data is based at least in part on the address and allocating the quantity of memory cells.

Aspect 13: The method or apparatus of aspect 12, further including operations, features, circuitry, logic, means, or instructions, or any combination thereof for the quantity of memory cells includes volatile memory cells.

Aspect 14: The method or apparatus of any of aspects 12 through 13, further including operations, features, circuitry, logic, means, or instructions, or any combination thereof for the quantity of memory cells includes non-volatile memory cells.

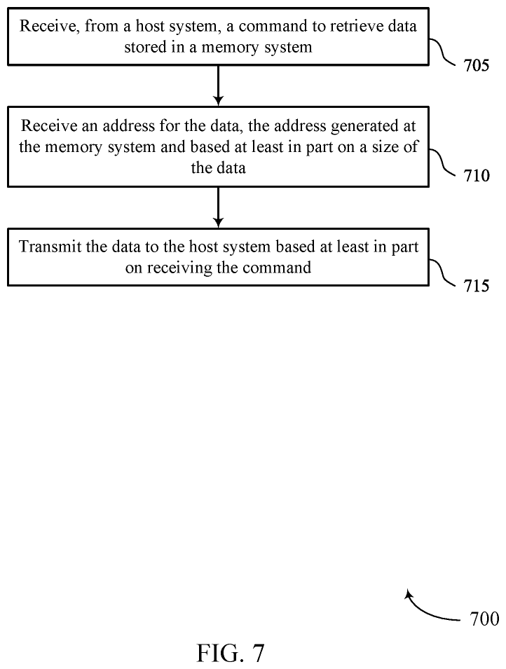

FIG. 7 shows a flowchart illustrating a method 700 that supports memory address management techniques in accordance with examples as disclosed herein. The operations of method 700 may be implemented by a memory system or its components as described herein. For example, the operations of method 700 may be performed by a memory system as described with reference to FIGS. 1 through 4. In some examples, a memory system may execute a set of instructions to control the functional elements of the device to perform the described functions. Additionally or alternatively, the memory system may perform aspects of the described functions using special-purpose hardware.

At 705, the method may include receiving, from a host system, a command to retrieve data stored in a memory system. The operations of 705 may be performed in accordance with examples as disclosed herein. In some examples, aspects of the operations of 705 may be performed by a command component 425 as described with reference to FIG. 4.

At 710, the method may include receiving an address for the data, the address generated at the memory system and based at least in part on a size of the data. The operations of 710 may be performed in accordance with examples as disclosed herein. In some examples, aspects of the operations of 710 may be performed by an address component 430 as described with reference to FIG. 4.

At 715, the method may include transmitting the data to the host system based at least in part on receiving the command. The operations of 715 may be performed in accordance with examples as disclosed herein. In some examples, aspects of the operations of 715 may be performed by a data component 435 as described with reference to FIG. 4.

In some examples, an apparatus as described herein may perform a method or methods, such as the method 700. The apparatus may include, features, circuitry, logic, means, or instructions (e.g., a non-transitory computer-readable medium storing instructions executable by a processor), or any combination thereof for performing the following aspects of the present disclosure:

Aspect 15: The method or apparatus, including operations, features, circuitry, logic, means, or instructions, or any combination thereof for receiving, from a host system, a command to retrieve data stored in a memory system; receiving an address for the data, the address generated at the memory system and based at least in part on a size of the data; and transmitting the data to the host system based at least in part on receiving the command.

Aspect 16: The method or apparatus of aspect 15, further including operations, features, circuitry, logic, means, or instructions, or any combination thereof for retrieving, based at least in part on receiving the command and the address, the data from the memory system using the address generated at the memory system, where transmitting the data is based at least in part on retrieving the data.

Aspect 17: The method or apparatus of any of aspects 15 through 16, further including operations, features, circuitry, logic, means, or instructions, or any combination thereof for generating, based at least in part on receiving the command and the address generated at the memory system, a physical address associated with the data, where transmitting the data is based at least in part on generating the physical address.

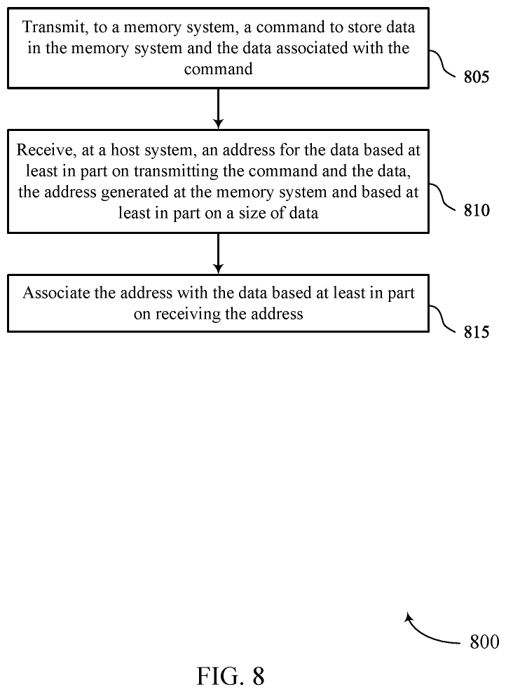

FIG. 8 shows a flowchart illustrating a method 800 that supports memory address management techniques in accordance with examples as disclosed herein. The operations of method 800 may be implemented by a host system or its components as described herein. For example, the operations of method 800 may be performed by a host system as described with reference to FIGS. 1 through 3 and 5. In some examples, a host system may execute a set of instructions to control the functional elements of the device to perform the described functions. Additionally or alternatively, the host system may perform aspects of the described functions using special-purpose hardware.

At 805, the method may include transmitting, to a memory system, a command to store data in the memory system and the data associated with the command. The operations of 805 may be performed in accordance with examples as disclosed herein. In some examples, aspects of the operations of 805 may be performed by a command component 525 as described with reference to FIG. 5.

At 810, the method may include receiving, at a host system, an address for the data based at least in part on transmitting the command and the data, the address generated at the memory system and based at least in part on a size of data. The operations of 810 may be performed in accordance with examples as disclosed herein. In some examples, aspects of the operations of 810 may be performed by an address component 530 as described with reference to FIG. 5.

At 815, the method may include associating the address with the data based at least in part on receiving the address. The operations of 815 may be performed in accordance with examples as disclosed herein. In some examples, aspects of the operations of 815 may be performed by an association component 535 as described with reference to FIG. 5.

In some examples, an apparatus as described herein may perform a method or methods, such as the method 800. The apparatus may include, features, circuitry, logic, means, or instructions (e.g., a non-transitory computer-readable medium storing instructions executable by a processor), or any combination thereof for performing the following aspects of the present disclosure:

Aspect 18: The method or apparatus, including operations, features, circuitry, logic, means, or instructions, or any combination thereof for transmitting, to a memory system, a command to store data in the memory system and the data associated with the command; receiving, at a host system, an address for the data based at least in part on transmitting the command and the data, the address generated at the memory system and based at least in part on a size of data; and associating the address with the data based at least in part on receiving the address.

Aspect 19: The method or apparatus of aspect 18, further including operations, features, circuitry, logic, means, or instructions, or any combination thereof for storing the address at the host system based at least in part on associating the address with the data.

Aspect 20: The method or apparatus of any of aspects 18 through 19, further including operations, features, circuitry, logic, means, or instructions, or any combination thereof for storing the command at the host system based at least in part on transmitting the command, where receiving the address is based at least part on storing the command.

It should be noted that the methods described above describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. A method, comprising:
receiving, from a host system, a command to store data in a memory system and the data associated with the command, wherein the command from the host system does not include a logical address associated with the data;
generating, at the memory system, an address to store the data based at least in part on receiving the command and the data, the address based at least in part on a size of the data;
transmitting the address to the host system based at least in part on generating the address; and
storing the data at a location indicated by the address based at least in part on generating the address.

2. (canceled)

3. The method of claim 1, further comprising:
identifying the size of the data based at least in part on receiving the command and the data, wherein generating the address is based at least in part on the identified size of the data.

4. The method of claim 3, wherein the command includes a size of the data and identifying the size of the data is based at least in part on the size included in the command.

5. The method of claim 1, further comprising:
using a pointer of the memory system that indicates one or more memory cells available to store the data based at least in part on the size of the data, wherein generating the address is based at least in part on using the pointer.

6. The method of claim 5, further comprising:
identifying a starting physical address of the memory system for the data based at least in part on the pointer, wherein generating the address is based at least in part on identifying the starting physical address.

7. The method of claim 5, further comprising:
updating the pointer based at least in part on storing the data and the size of the data, wherein the address comprises a value of the pointer, a name of the pointer, an address of the pointer, or a combination thereof.

8. The method of claim 1, wherein generating the address comprises:
identifying a physical address to store the data based at least in part on a pointer of the memory system and the size of the data; and
generating a logical address based at least in part on the physical address, wherein the address that is transmitted to the host system comprises the logical address.

9. The method of claim 8, further comprising:
receiving, from the host system, a second command to retrieve a mapping between the physical address and the logical address;
receiving, from the host system, a security parameter associated with the second command to retrieve the mapping; and
transmitting at least a portion of the mapping to the host system based at least in part on receiving the second command to retrieve the mapping and the security parameter.

10. The method of claim 8, wherein storing the data further comprises:
storing the data at the location indicated by the pointer of the memory system, wherein identifying the physical address is based at least in part on the pointer, and wherein storing the data at least partially overlaps in time with generating the address.

11. The method of claim 1, wherein generating the address comprises:
identifying a physical address to store the data based at least in part on a pointer of the memory system and the size of the data, wherein the address that is transmitted to the host system comprises the physical address.

12. The method of claim 1, further comprising:
allocating a quantity of memory cells for the data associated with the command based at least in part on the size of the data, wherein storing the data is based at least in part on the address and allocating the quantity of memory cells.

13. The method of claim 12, wherein the quantity of memory cells comprises volatile memory cells.

14. The method of claim 12, wherein the quantity of memory cells comprises non-volatile memory cells.

15. A method, comprising:
receiving, from a host system, a command to store data in a memory system and the data associated with the command, wherein the command from the host system does not include a logical address associated with the data;
generating, at the memory system, an address to store the data based at least in part on receiving the command and the data, the address based at least in part on a size of the data:
receiving, from the host system, a second command to retrieve the data stored in the memory system;
receiving the address for the data; and
transmitting the data to the host system based at least in part on receiving the second command.

16. The method of claim 15, further comprising:
retrieving, based at least in part on receiving the second command and the address, the data from the memory system using the address generated at the memory system, wherein transmitting the data is based at least in part on retrieving the data.

17. The method of claim 15, further comprising:
generating, based at least in part on receiving the second command and the address generated at the memory system, a physical address associated with the data, wherein transmitting the data is based at least in part on generating the physical address.

18. A method, comprising:
transmitting, to a memory system, a command to store data in the memory system and the data associated with the command;
receiving, at a host system, an address for the data based at least in part on transmitting the command and the data, the address generated at the memory system and based at least in part on a size of data; and
associating, by the host system, the address with the data based at least in part on receiving the address.

19. The method of claim 18, further comprising:
storing the address at the host system based at least in part on associating the address with the data.

20. The method of claim 18, further comprising:
storing the command at the host system after transmitting the command, wherein the address is received after storing the command.
